(19) United States
(12) Patent Application Publication
(10) Pub. No.: US 2013/0200238 A1
(43) Pub. Date: Aug. 8, 2013

(54) FASTENING DEVICE FOR HARD DISK DRIVE

(71) Applicants: AN-GANG LIANG, Shenzhen City (CN); PING-CHUAN DENG, Shenzhen City (CN)

(72) Inventors: AN-GANG LIANG, Shenzhen City (CN); PING-CHUAN DENG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/473,627

(22) Filed: May 17, 2012

(30) Foreign Application Priority Data
Feb. 6, 2012 (CN) 201210025114.2

(51) Int. Cl. H05K 7/00

(52) U.S. Cl. 248/310

(57) ABSTRACT

A fastening device for a hard disk drive (HDD) includes a bracket and a bottom plate. The bracket includes a base plate to support the HDD. Two latching tabs extend down from opposite sides of the base plate. A fastening tab extends out from a first end of the base plate. Two blocks protrude from the bottom plate. A hooking slot is defined in each block. The latching tabs are operable to engage in the hooking slots. A fastener is operable to extend through the fastening tab and engage in the bottom plate.

### BACKGROUND

1. Technical Field

The present disclosure relates to a device for fastening a hard disk drive (HDD).

2. Description of Related Art

Some servers with storage functions require a large number of HDDs. Therefore, the large number of HDDs is mounted in a chassis of a server, resulting in difficulty with space layout in the chassis.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a fastening device and a first hard disk drive (HDD).

FIG. 2 is an exploded, isometric view of the fastening device of FIG. 1 and a second HDD.

FIG. 3 is an enlarged view of a circled portion III of FIG. 1.

FIG. 4 is an assembled, isometric view of FIG. 1.

FIG. 5 is an assembled, isometric view of FIG. 2.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

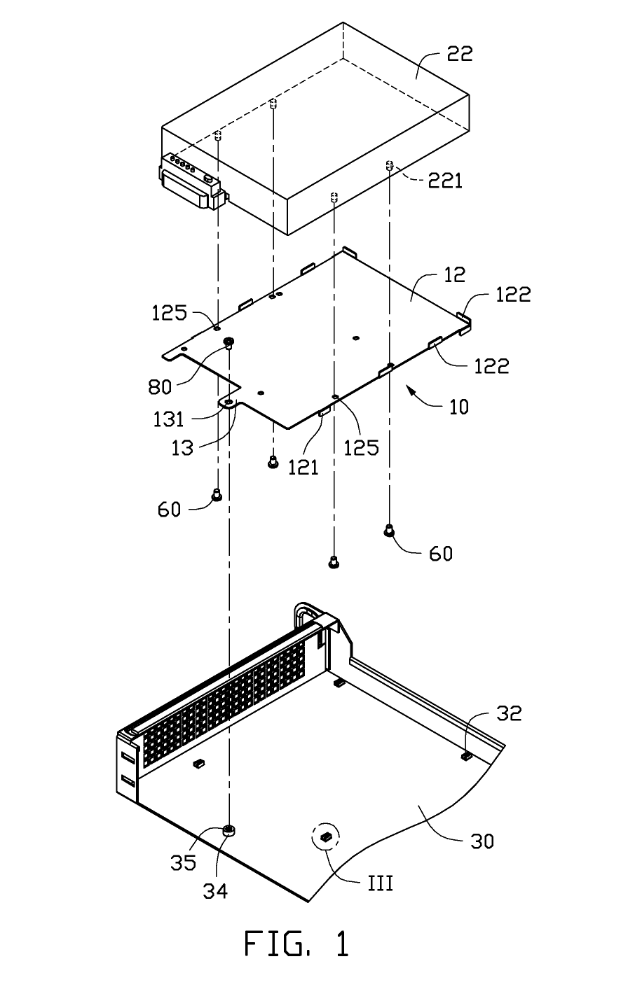

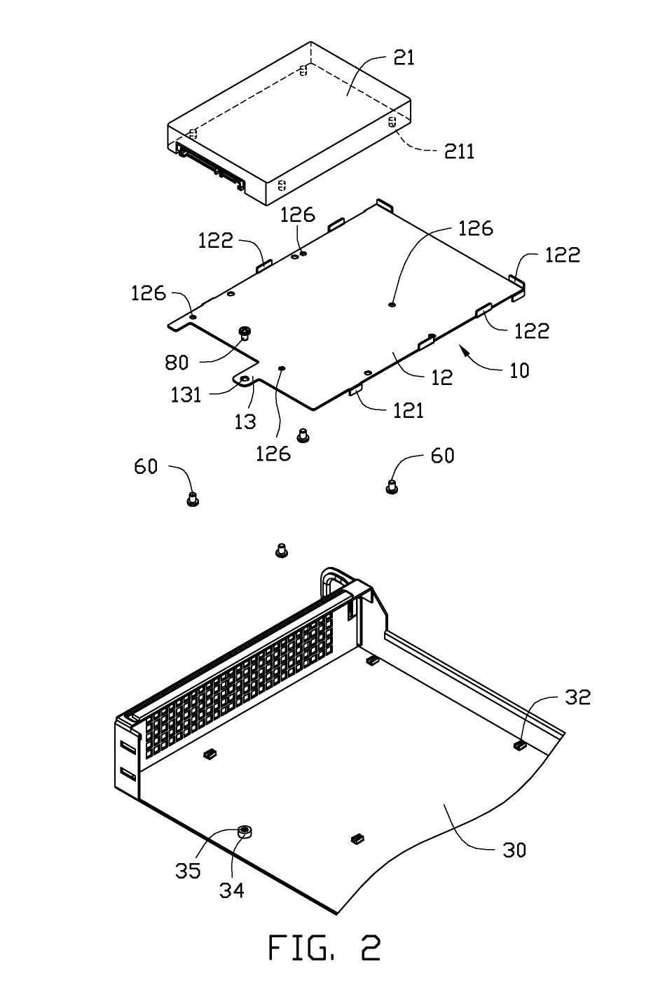

FIGS. 1 and 2 show an exemplary embodiment of a fastening device for fastening a 3.5 inch first hard disk drive (HDD) 22 or a 2.5 inch second HDD 21. The fastening device includes a bracket 10 and a bottom plate 30. Four locking holes 221 are defined in a bottom surface of the first HDD 22. Four locking holes 211 are defined in a bottom surface of the second HDD 21.

The bracket 10 includes a substantially rectangular base plate 12. A fastening tab 13 extends out from a first end of the base plate 12. A through hole 131 is defined in the fastening tab 13. Two latching tabs 121 perpendicularly extend down from opposite ends of each of opposite sides of the base plate 12. Two stop tabs 122 perpendicularly extend up from each of the sides and a second end of the base plate 12 opposite to the first end. Four first holes 125 are defined in the base plate 12, respectively adjacent to the opposite sides of the base plate 12, corresponding to the locking holes 221 of the first HDD 22. Four second holes 126 are defined in the base plate 12, corresponding to the locking holes 211 of the second HDD 21.

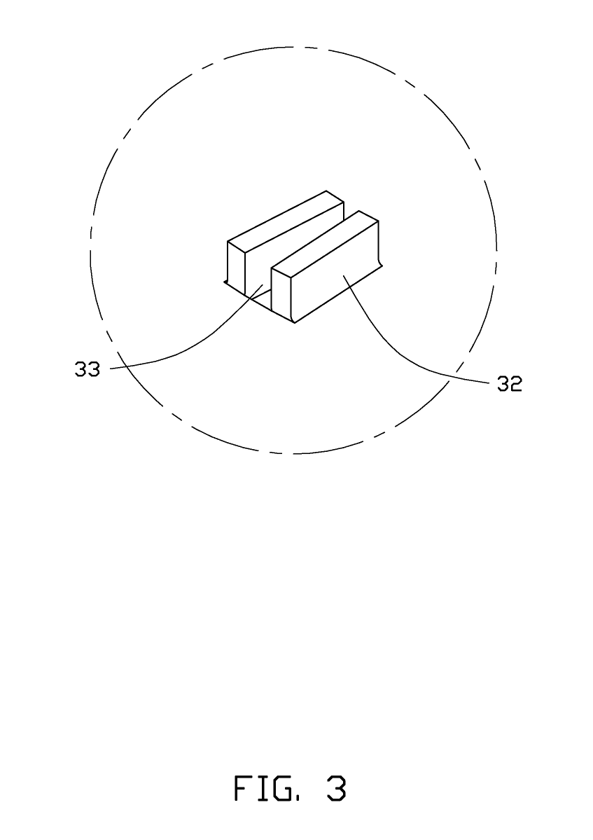

FIGS. 1 and 3 show four blocks 32 protruding up from the bottom plate 30. A hooking slot 33 is defined in each block 32, extending through opposite ends and a top surface of the block 32. The hooking slot 33 gradually narrows from a first end of the block 32 to a second end of the block 32 opposite to the first end. A protrusion 34 protrudes up from the bottom plate 30, beside the blocks 32. A mounting hole 35 is defined in a top of the protrusion 34.

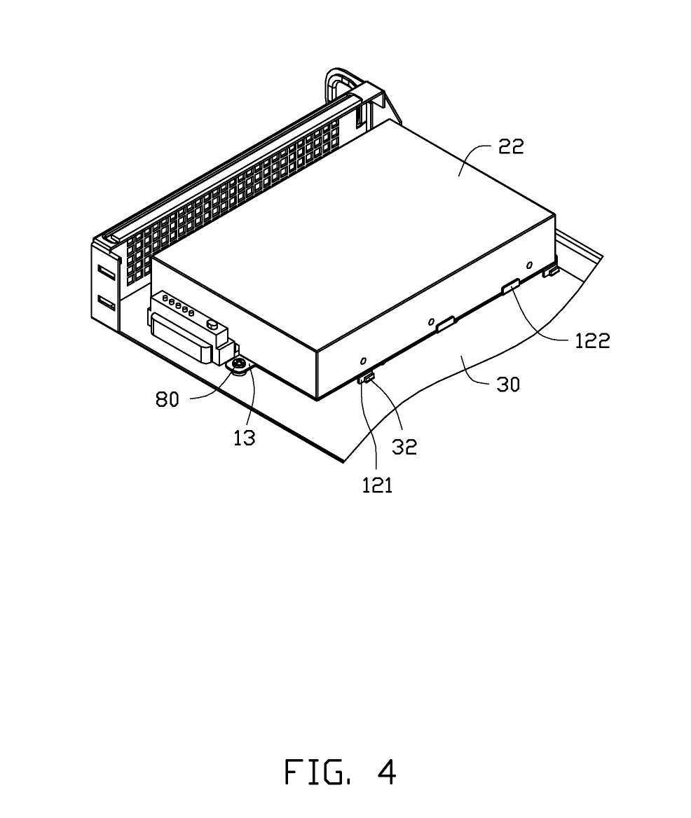

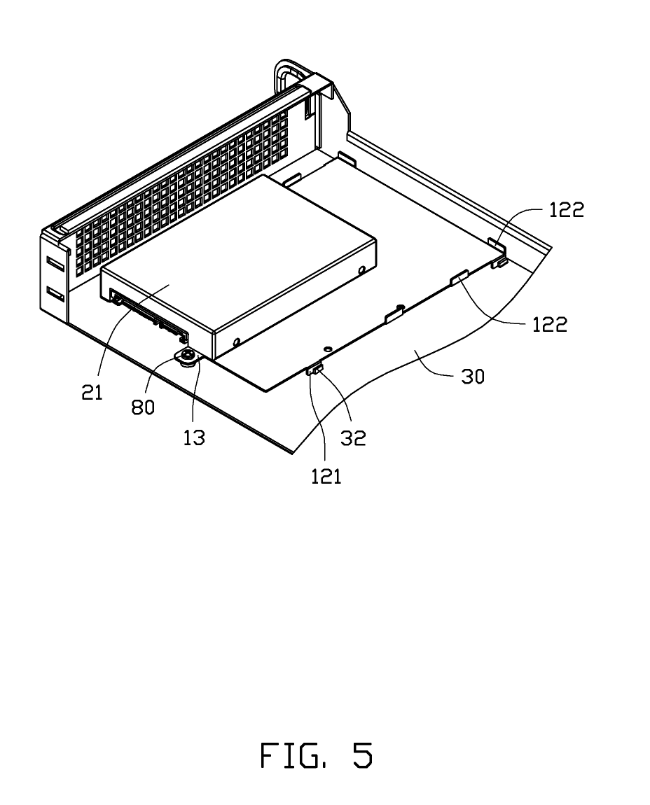

FIGS. 4 and 5 show in assembly, to assemble the first HDD 22, the first HDD 22 is placed on the base plate 12 and abutted against inner surfaces of the stop tabs 122. Four screws 60 extend through the corresponding first holes 125 and then engage in the corresponding locking holes 221. The latching tabs 121 engage in the corresponding hooking slots 33 through the first ends of the corresponding hooking slots 33. A fastener 80, such as a screw, extends through the through hole 131 and engages in the mounting hole 35. Therefore, the first HDD 20 is fastened to the bottom plate 30.

To assemble the second HDD 21, the second HDD 21 is placed on the base plate 12 and abutted against a stop tab 122 at a corresponding side of the bracket 10. Four screws 60 extend through the corresponding second holes 126 and engage in the corresponding locking holes 211. The second HDD 21 is then fastened to the bottom plate 30.

The bracket 10 is only fastened to the bottoms of the HDD 21 and 22, occupying a relatively small space, so that the chassis may receive more HDDs.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A fastening device for a hard disk drive (HDD), comprising:
a bracket comprising a base plate to support the HDD, two latching tabs extending down from opposite sides of the base plate, a fastening tab extending out from a first end of the base plate; and
a bottom plate, two blocks protruding from the bottom plate, each block defining a hooking slot therein, the latching tabs operable to respectively engage in the hooking slots, a fastener operable to extend through the fastening tab and then engage in the bottom plate.

2. The fastening device of claim 1, wherein each hooking slot gradually narrows from a first end of the block to a second end of the block opposite to the first end, the latching tabs engage in the corresponding hooking slots through the first ends.

3. The fastening device of claim 1, wherein a protrusion protrudes from the bottom plate, a mounting hole is defined in the protrusion, the fastening tab defines a through hole, the fastener extends through the through hole and then engages in the mounting hole.

4. The fastening device of claim 1, wherein the base plate defines a group of holes to fix the HDD.

5. The fastening device of claim 1, wherein a plurality of stop tabs extends up from opposite sides of the base plate to sandwich the HDD.

6. The fastening device of claim 1, wherein a stop tab extends up from a second end of the base plate opposite to the first end, to abut against a corresponding end of the HDD.

7. A fastening device for fastening a first hard disk drive (HDD) or a second HDD, the first HDD has a larger size than the second HDD, the fastening device comprising:
a bracket comprising a base plate, the base plate defining a first group holes for fixing the first HDD and defining a second group holes for fixing the second HDD, two latching tabs extending down from opposite sides of the base plate, a fastening tab extending out from a first end of the base plate; and
a bottom plate, two blocks protruding from the bottom plate, each block defining a hooking slot therein, the latching tabs operable to respectively engage in the hooking slots, a fastener operable to extend through the fastening tab and then engage in the bottom plate.

8. The fastening device of claim 7, wherein each hooking slot gradually narrows from a first end of the block to a second end of the block opposite to the first end, the latching tabs engage in the corresponding hooking slots through the first ends.

9. The fastening device of claim 7, wherein a protrusion protrudes from the bottom plate, a mounting hole is defined in the protrusion, the fastening tab defines a through hole, the fastener extends through the through hole and then engages in the mounting hole.

10. The fastening device of claim 7, wherein a plurality of first stop tabs extends up from one of opposite sides of the base plate to abut against a first sidewall of each of the first and second HDDs, a plurality of second stop tabs extends up from the other of opposite sides of the base plate to abut against a second sidewall of the first HDD.

11. The fastening device of claim 7, wherein a stop tabs extends up from a second end of the base plate opposite to the first end, to abut against a corresponding end of the first HDD.
